(19) United States
(12) Patent Application Publication
(10) Pub. No.: US 2022/0093683 A1
(43) Pub. Date: Mar. 24, 2022

(54) 3D HETEROGENEOUS INTEGRATED CRYSTALLINE PIEZOELECTRIC BULK ACOUSTIC RESONATORS

(71) Applicant: Intel Corporation, Santa Clara, CA (US)

(72) Inventors: Han Wui THEN, Portland, OR (US); Ibrahim BAN, Beaverton, OR (US); Paul B. FISCHER, Portland, OR (US); Kimin JUN, Portland, OR (US); Paul NORDEEN, Hillsboro, OR (US); Pratik KOIRALA, Portland, OR (US); Tushar TALUKDAR, Wilsonville, OR (US)

(21) Appl. No.: 17/031,719

(22) Filed: Sep. 24, 2020

(51) Int. Cl. H01L 27/20; H01L 29/16; H01L 29/20; H03H 9/02; H03H 9/17; H03H 9/54; H03H 9/56

(52) U.S. Cl. CPC H01L 27/20; H01L 29/16; H01L 29/2003; H03H 9/02031; H03H 9/564; H03H 9/175; H03H 9/176; H03H 9/545; H03H 9/562; H03H 9/173

(57) ABSTRACT

Embodiments disclosed herein include resonators and methods of forming such resonators. In an embodiment a resonator comprises a substrate, where a cavity is disposed into a surface of the substrate, and a piezoelectric film suspended over the cavity. In an embodiment, the piezoelectric film has a first surface and a second surface opposite from the first surface, and the piezoelectric film is single crystalline and has a thickness that is 0.5 μm or less. In an embodiment a first electrode is over the first surface of the piezoelectric film, and a second electrode is over the second surface of the piezoelectric film.

### TECHNICAL FIELD

Embodiments of the present disclosure relate to semiconductor devices, and more particularly to single crystalline bulk acoustic resonators.

### BACKGROUND

Communication bands continue to move to higher frequencies to support higher data rates. This requires RF filters with resonator resonance frequencies at frequencies above 5 GHz. In bulk acoustic resonators, the resonance frequencies are inversely proportional to the thickness of the piezoelectric film. AlN is one example of a piezoelectric film typically used in commercial resonators. In order to obtain resonant frequencies above 5 GHz, the thickness of the AlN needs to be less than 0.5 μm. However, the crystalline quality of the AlN deposited by sputtering techniques becomes unacceptably poor for thicknesses less than 0.5 μm, and the performance of the RF filter suffers.

### BRIEF DESCRIPTION OF THE DRAWINGS

FIG. 1A is a cross-sectional illustration of a resonator with a single crystalline piezoelectric film, in accordance with an embodiment.

FIG. 1B is a plan view illustration of the resonator in FIG. 1A, in accordance with an embodiment.

FIG. 1C is a cross-sectional illustration of a resonator with a single crystalline piezoelectric film with a tuning layer, in accordance with an embodiment.

FIGS. 2A-2I are cross-sectional illustrations of a process for forming a resonator with a single crystalline piezoelectric film, in accordance with an embodiment.

FIG. 3A is a cross-sectional illustration of a resonator with a single crystalline piezoelectric film with acoustic reflectors above and below the piezoelectric film, in accordance with an embodiment.

FIG. 3B is a cross-sectional illustration of a resonator with a single crystalline piezoelectric film with acoustic reflectors and a tuning layer over the piezoelectric film, in accordance with an embodiment.

FIGS. 4A-4H are cross-sectional illustrations of a process for forming a resonator with a single crystalline piezoelectric film, in accordance with an embodiment.

FIG. 5A is a cross-sectional illustration depicting a wafer level integration of a resonator with a single crystalline piezoelectric film, in accordance with an embodiment.

FIG. 5B is a cross-sectional illustration depicting a wafer level integration of a resonator with acoustic reflectors, in accordance with an embodiment.

FIG. 5C is a cross-sectional illustration depicting a wafer level integration of a resonator with acoustic reflectors and high quality passives above the resonator, in accordance with an embodiment.

FIG. 6A is a cross-sectional illustration of a package level integration of a resonator in an RF die, in accordance with an embodiment.

FIG. 6B is a cross-sectional illustration of a package level integration of a resonator in an RF die using an on die interconnect (ODI) integration, in accordance with an embodiment.

FIG. 6C is a cross-sectional illustration of a package level integration of a resonator in an RF die using an embedded multi-die interconnect bridge (EMIB) integration, in accordance with an embodiment.

FIG. 7 is a schematic of a computing device built in accordance with an embodiment.

### EMBODIMENTS OF THE PRESENT DISCLOSURE

Described herein are single crystalline bulk acoustic resonators for frequencies above 5 GHz, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, continued scaling of resonator thicknesses below 0.5 μm is not currently possible. This is due to the crystallinity of the resonator film being degraded at such small thicknesses when a physical deposition process, such as sputtering, is used. However, thin resonator films may be provided using other deposition techniques, such as metalorganic chemical vapor deposition (MOCVD) or molecular-beam epitaxy (MBE). However, MOCVD and MBE techniques require a crystalline template to form the single crystalline resonator film. This prohibits the deposition and patterning of bottom (underlying) metal electrodes. Without the ability to form the bottom electrode and bottom acoustic reflector structures, and to release the thin film from the crystalline template, there is no way to harness the advantageous longitudinal piezoelectric modes to obtain the electromechanical resonances required for RF filtering.

Accordingly, embodiments disclosed herein provide assembly processes that allow for single crystalline resonator films to be formed and integrated into a functional resonator. For example, the resonator film may be grown on single crystalline substrate (e.g., silicon). A first electrode is formed on the exposed top surface of the resonator film. Subsequently, the single crystalline resonator film is transferred to a second substrate, and the bottom surface of the resonator film is exposed. The second electrode may then be formed on the exposed surface, thereby providing an electrode on two surfaces of the resonator film.

In some embodiments, the resonator film is unconstrained and free to oscillate. For example, release vias are formed through the resonator film to allow a portion to resonate above a cavity in an underlying substrate. In other embodiments, the resonator film is constrained. However, resonance may still be observed due to acoustic reflectors that are formed above and below the resonator film. Embodiments disclosed herein include integration of the resonator at the wafer level. In other embodiments, integration of the resonator is implemented at the package level.

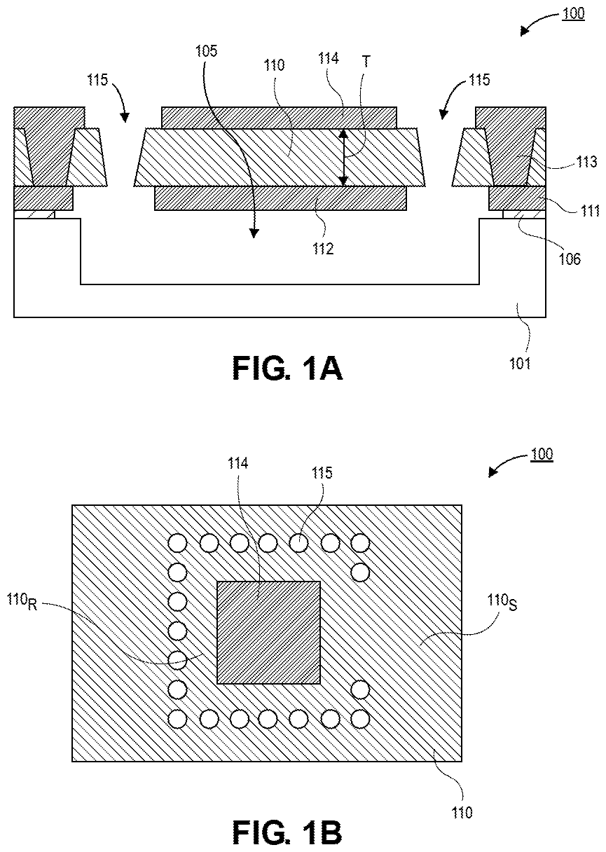

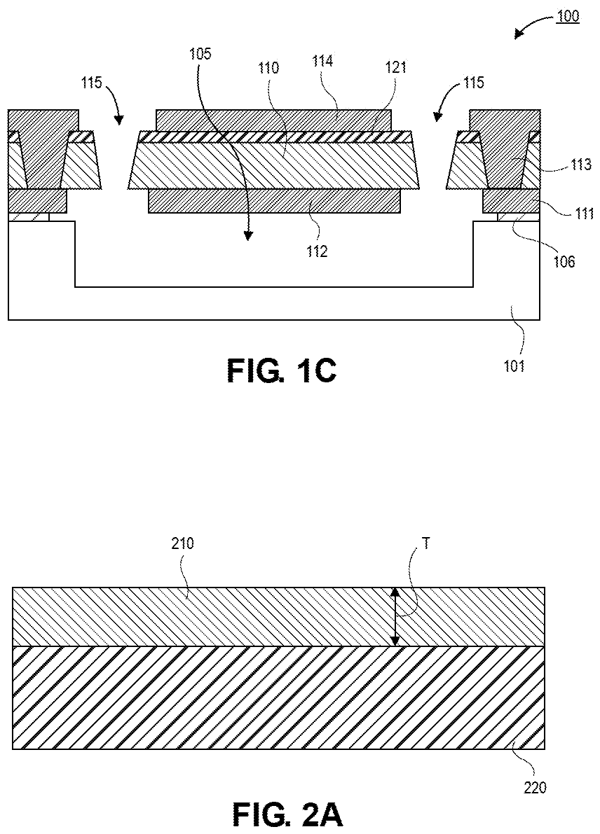

Referring now to FIG. 1A, a cross-sectional illustration of a resonator 100 is shown, in accordance with an embodiment. In an embodiment, the resonator comprises a substrate 101 and a resonator film 110. The substrate 101 may be any suitable semiconductor substrate. For example, the substrate 101 may include silicon. In an embodiment, a cavity 105 is provided into the substrate 101. The cavity 105 may be sized to allow for a portion of the resonator film 110 to freely oscillate.

In an embodiment, the resonator film 110 comprises a crystalline piezoelectric material. In a particularly embodiment, the piezoelectric material is substantially single crystalline, or completely single crystalline. In an embodiment, the resonator film 110 has a thickness T. The thickness T may be a suitable thickness to allow for resonant frequencies that are greater than approximately 5 GHz. For example, the resonant frequency may be between approximately 5 GHz and 30 GHz. In an embodiment, the thickness T may be approximately 0.5 μm or less. For example, the thickness T may be between approximately 1 nm and 0.5 μm. It is to be appreciated that a highly crystalline piezoelectric material with thicknesses at or below approximately 0.5 μm is not obtainable using traditional sputtering processes or other physical deposition processes. As will be described in greater detail below, the formation of the resonator film 110 is implemented with an MOCVD process or a MBE process over a single crystalline substrate. The resonator film 110 may be characterized with a rocking curve measurement of approximately 0.3 degrees (FWHM) or lower. In an embodiment, the resonator film 110 may be any suitable piezoelectric material such as, but not limited to AlN, ScAlN, lead zirconium titanate (PZT), LiNbO₃, and LiTaO₃.

In an embodiment, a first electrode 112 may be disposed over a first surface (e.g., bottom surface) of the resonator film 110, and a second electrode 114 may be disposed over a second surface (e.g., top surface) of the resonator film 110. In an embodiment, the first electrode 112 may be electrically coupled to the second surface of the resonator film 110 by a via 113 through the resonator film 110. The via 113 may land on a pad 111 that is electrically coupled to the first electrode 112. The pad 111 may be electrically isolated from the substrate 101 by an insulator layer 106.

In an embodiment, the resonator film 110 is released from the structure to allow oscillation by a plurality of release vias 115. In an embodiment, the release vias 115 may be formed with a laser drilling process. As such, the release vias 115 may have a tapered profile as is characteristic of laser drilling processes. However, in other embodiments, the release vias 115 may have substantially vertical sidewalls, as would be the case when mechanical drilling or plasma-based etching is used to form the release vias 115.

In FIG. 1A, the cross-section passes through a pair of release vias 115. In this cross-section the central portion of the resonator film 110 appears to be floating. However, it is to be appreciated that the central resonator film 110 may still be attached to the periphery of the resonator film 110 out of the plane of FIG. 1A.

Referring now to FIG. 1B, a plan view illustration of the resonator 100 is shown, in accordance with an embodiment. As shown, the release vias 115 are positioned around a perimeter of a resonator portion 110_{R} of the resonator film 110. In an embodiment, the electrodes 112/114 are provided over the resonator portion 110_{R} of the resonator film 110. Electrical connections to the electrodes 112/114 may be provided by traces (not shown) that pass between release vias 115. For example, a spacing between the release vias 115 is provided on the right hand side of the electrode 114. However, in other embodiments, the release vias 115 may have a substantially regular spacing around the electrode 114 that is large enough to accommodate the electrical connections to the electrodes 112/114. The portion of the resonator film 110 outside of the release vias 115 may be referred to as the static portion 110_{S} of the resonator film 110 since the static portion 110_{S} is substantially free from oscillation. In the illustrated embodiment, the release vias 115 are shown as substantially circular in shape. However, it is to be appreciated that the release vias 115 may have any shape, such as rectangular.

Referring now to FIG. 1C, a cross-sectional illustration of a resonator 100 is shown, in accordance with an additional embodiment. In an embodiment, the resonator 100 in FIG. 1C may be substantially similar to the resonator 100 in FIG. 1A, with the exception that a tuning layer 121 is provided over the resonator film 110. The tuning layer 121 may be used to modulate the resonant frequency of the resonator 100. In an embodiment, the tuning layer 121 may be silicon. As will be described below, the tuning layer 121 may be a residual portion of the substrate on which the resonator film 110 is grown. As such, the tuning layer 121 may be present over the entire resonator film 110 (i.e., the resonator portion 110_{R} and the static portion 110_{S}). In an embodiment, a thickness of the tuning layer 121 may be less than a thickness of the resonator film 110. For example, the tuning layer 121 may have a thickness between approximately 1 nm and approximately 0.5 μm.

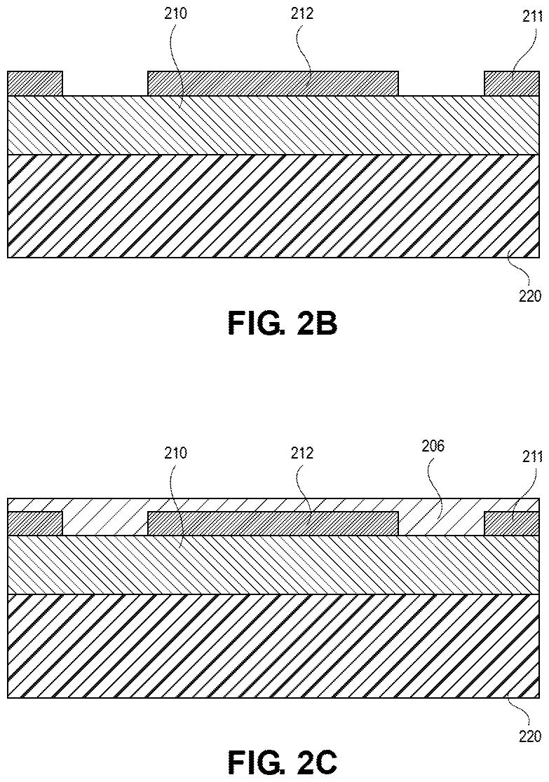

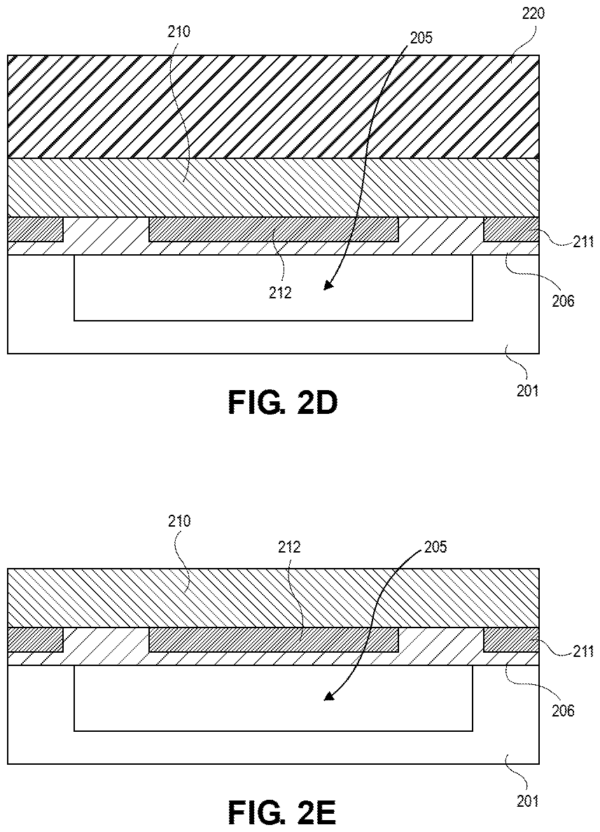

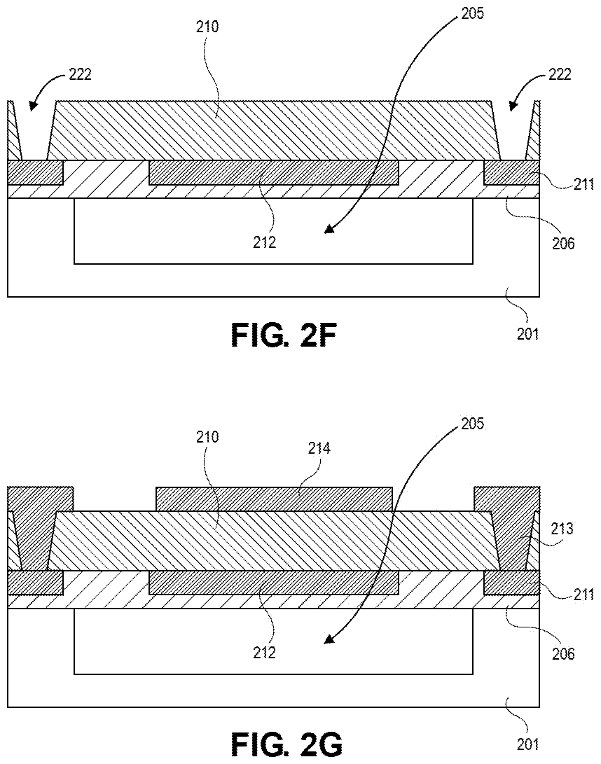

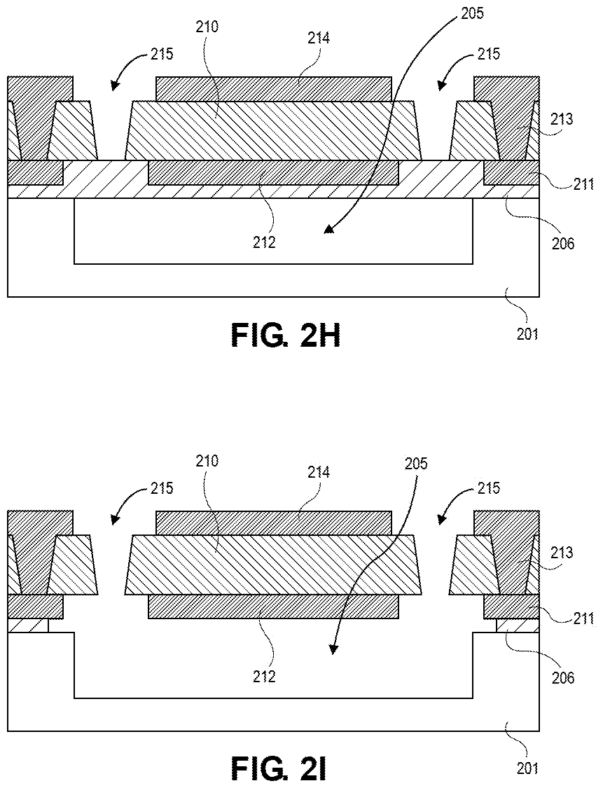

Referring now to FIGS. 2A-2I, a series of cross-sectional illustrations depicting a process for forming a resonator is shown, in accordance with an embodiment. The resonator fabricated in FIGS. 2A-2I may be substantially similar to the resonators 100 illustrated in FIGS. 1A-1C.

Referring now to FIG. 2A, a cross-sectional illustration of a substrate 220 and resonator film 210 is shown, in accordance with an embodiment. In an embodiment, the substrate 220 may be a single crystalline substrate, such as single crystalline Si. In a particular embodiment, the substrate 220 may be a (111) silicon substrate. In an embodiment, the resonator film 210 may be grown over the substrate 220. For example, the resonator film 210 may be grown with an MOCVD or MBE process. Since a single crystalline substrate is used as the base, a highly crystalline resonator film 210 may be provided, even at small thicknesses T. For example, the thickness T may be between approximately 1 nm and approximately 0.5 μm.

Referring now to FIG. 2B, a cross-sectional illustration after a first electrode 212 is disposed over the resonator film 210 is shown, in accordance with an embodiment. The first electrode 212 may be any suitable conductive material, such as copper. In an embodiment, pads 211 may also be formed during the formation of the first electrode 212. The pads 211 may be electrically coupled to the first electrode 212 by one or more traces out of the plane of FIG. 2B.

Referring now to FIG. 2C, a cross-sectional illustration after an insulating layer 206 is disposed over the first electrode 212, the pads 211, and the resonator film 210 is shown, in accordance with an embodiment. In an embodiment, the insulating layer 206 may be an oxide, such as, but not limited to SiO₂.

Referring now to FIG. 2D, a cross-sectional illustration after the structure is attached to a substrate 201 is shown, in accordance with an embodiment. The substrate 201 may be attached with any suitable process, such as wafer-to-wafer bonding. In an embodiment, the substrate 201 may comprise a cavity 205. The cavity 205 is aligned with the first electrode 212. In an embodiment, the substrate 201 may be any substrate material. For example, the substrate 201 may be a silicon substrate.

Referring now to FIG. 2E, a cross-sectional illustration of the structure after the substrate 220 is removed is shown, in accordance with an embodiment. The complete removal of the substrate 220 may result in a resonator similar to the resonator 100 shown in FIG. 1A. However, the entirety of the substrate 220 may not be removed in some embodiments. The residual portion of the substrate 220 may be used as a tuning layer, similar to the tuning layer 121 shown in the embodiment illustrated in FIG. 1C. Moving forward in the process flow, an embodiment where the complete removal of the substrate 220 is shown, but it is to be appreciated that similar processing operations may be implemented with a residual portion of the substrate 220 remaining.

The substrate 220 may be removed (partially or completely) with any suitable process. For example, a grinding or polishing process may be used to remove the substrate 220. In an alternative embodiment, an ion cutting process may be used to remove some or all of the substrate 220. An ion cutting process may include implanting hydrogen into the substrate 220 to a depth where the cut is desired to be made. A subsequent annealing process may be used to split the substrate 220 at a desired position.

Referring now to FIG. 2F, a cross-sectional illustration of the structure after via openings 222 are formed through the resonator film 210 is shown, in accordance with an embodiment. The via openings 222 are positioned over the pads 211. In an embodiment, the via openings 222 may be formed with a laser drilling process, or the like. When laser drilling is used, sidewall surfaces of the via openings 222 may have a tapered profile.

Referring now to FIG. 2G, a cross-sectional illustration of the structure after a second electrode 214 is formed over the exposed surface of the resonator film 210 is shown, in accordance with an embodiment. In an embodiment, the second electrode 214 is positioned substantially above the first electrode 212. The plating process used to form the second electrode 214 may also result in the formation of vias 213 in the via openings 222. The second electrode 214 may be any suitable conductive material, such as molybdenum, tungsten, aluminum, tantalum, copper or alloys of such.

Referring now to FIG. 2H, a cross-sectional illustration of the structure after release vias 215 are formed through the resonator film 210 is shown, in accordance with an embodiment. The release vias 215 may mechanically decouple a substantial portion of an interior region of the resonator film 210 that is proximate to the first electrode 212 and the second electrode 214 from an exterior region of the resonator film 210. In an embodiment, the release vias 215 may have a tapered profile characteristic of a laser drilling process. However, in other embodiments, the release vias 215 may have substantially vertical sidewalls.

Referring now to FIG. 2I, a cross-sectional illustration of the structure after portions of the insulating layer 206 are removed is shown, in accordance with an embodiment. In an embodiment, the insulating layer 206 may be removed with an etching process. Residual portions of the insulating layer 206 may remain in some embodiments. For example, portions of the insulating layer 206 are shown below the pads 211. Removal of the insulating layer 206 releases the resonator portion of the resonating film 210 between the first electrode 212 and the second electrode 214 so that it is free to oscillate substantially unobstructed.

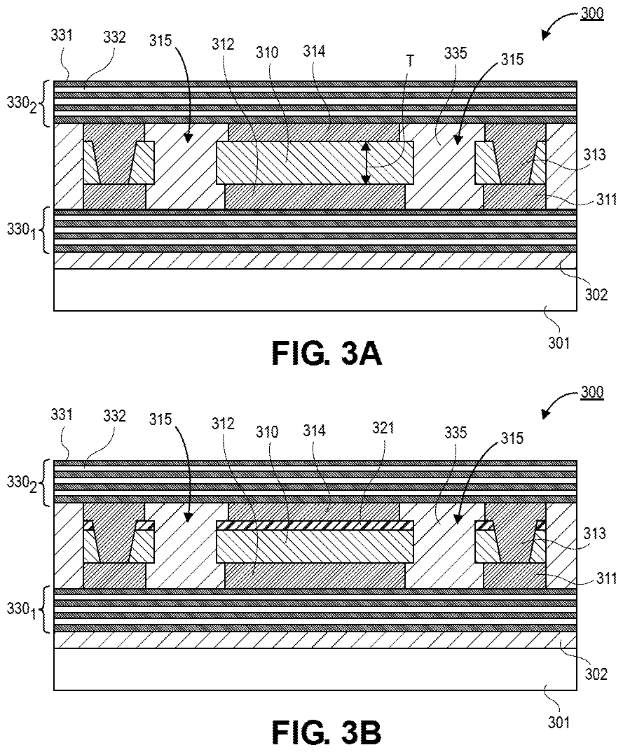

In the embodiments described above in FIGS. 1A-2I, the resonator is allowed to oscillate freely. That is, there is no material above or below the resonating portion that can obstruct the free movement of the piezoelectric material. However, embodiments are not limited to such configurations. For example, FIGS. 3A and 3B illustrate resonators 300 that are fully embedded. In such embodiments, acoustic reflectors are provided above and below the resonator film.

An acoustic reflector is a structure that is suitable for reflecting the vibrations in adjacent layers. Particularly, the acoustic reflector comprises alternating layers of a heavy or high acoustic impedance material (e.g., a hard or stiff material) and layers of a light or low acoustic impedance material (e.g., a soft material). In an embodiment, the individual layers may have a thickness between 100 nm and 1,000 nm. In a particular embodiment, the heavy acoustic impedance layers comprise W and the light acoustic impedance layers comprise SiO₂.

Referring now to FIG. 3A, a cross-sectional illustration of a resonator 300 is shown, in accordance with an embodiment. In an embodiment, the resonator 300 comprises a substrate 301. The substrate 301 may be a semiconductor material, such as, but not limited to silicon. In an embodiment, the substrate 301 is coupled to a first acoustic reflector 330₁ by an insulating layer 302, such as an oxide. The first acoustic reflector 330₁ may comprise alternating light acoustic impedance layers 331 and heavy acoustic impedance layers 332. For example, the alternating layers 331 and 332 may comprise W and SiO₂.

In an embodiment, a first electrode 312 is provided directly above and in contact with the first acoustic reflector 330₁. The first electrode 312 may be electrically coupled to pads 311 that are also over the first acoustic reflector 330₁. The first electrode 312 may be coupled to the pads 311 by traces that are out of the plane of FIG. 3A.

In an embodiment, a resonator film 310 is disposed over the first electrode 312. In an embodiment the resonator film 310 comprises a crystalline piezoelectric material. In a particularly embodiment, the piezoelectric material is substantially single crystalline, or completely single crystalline. In an embodiment, the resonator film 310 has a thickness T. The thickness T may be a suitable thickness to allow for resonant frequencies that are greater than approximately 5 GHz. For example, the resonant frequency may be between approximately 5 GHz and 30 GHz. In an embodiment, the thickness T may be approximately 0.5 μm or less. For example, the thickness T may be between approximately 1 nm and 0.5 μm. It is to be appreciated that a highly crystalline piezoelectric material with thicknesses at or below approximately 0.5 μm is not obtainable using traditional sputtering processes or other physical deposition processes. As will be described in greater detail below, the formation of the resonator film 310 is implemented with an MOCVD process or a MBE process over a single crystalline substrate. The resonator film 310 may be characterized with a rocking curve measurement of approximately 0.3 degrees (FWHM) or lower. In an embodiment, the resonator film 310 may be any suitable piezoelectric material such as, but not limited to AlN, ScAlN, PZT, LiNbO₃, and LiTaO₃.

In an embodiment, release vias 315 may be formed through the resonator film 310. The release vias 315 may be filled with an insulative material 335, such as, but not limited to, SiO₂. Additionally, conductive vias 313 may be formed through the resonator film 310 to electrically couple pads 311 to the opposite side of the resonator film 310. In an embodiment, a second electrode 314 is positioned over the surface of the resonator film 310. The second electrode 314 is substantially aligned with the first electrode 312.

In an embodiment, a second acoustic reflector 330₂ is disposed over (and in contact with) the second electrode 314. The second acoustic reflector 330₂ is substantially identical to the first acoustic reflector 330₁. In an alternative embodiment, the second acoustic reflector 330₂ may be omitted, thereby allowing the resonator film 310 to move freely in the positive Z-direction.

Referring now to FIG. 3B, a cross-sectional illustration of a resonator 300 is shown, in accordance with an additional embodiment. The resonator 300 in FIG. 3B may be substantially similar to the resonator 300 in FIG. 3A, with the exception of a tuning layer 321 being disposed over a top surface of the resonator film 310. The tuning layer 321 may be used to modulate the resonant frequency of the resonator 300. In an embodiment, the tuning layer 321 may be silicon. As will be described below, the tuning layer may be a residual portion of the substrate on which the resonator film 310 is grown. As such, the tuning layer 321 may be present over the entire resonator film 310 (i.e., the resonator portion and the static portion). In an embodiment, a thickness of the tuning layer 321 may be less than a thickness of the resonator film 310. For example, the tuning layer 321 may have a thickness between approximately 1 nm and approximately 0.5 μm.

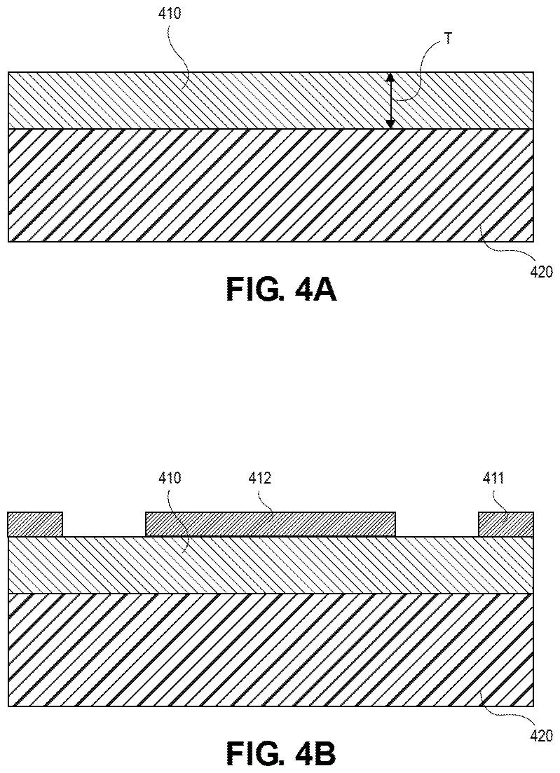

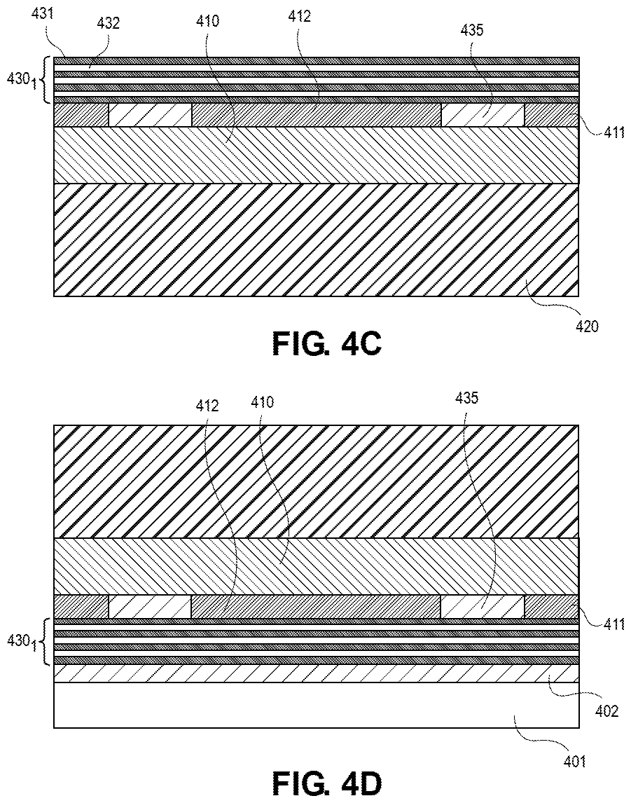

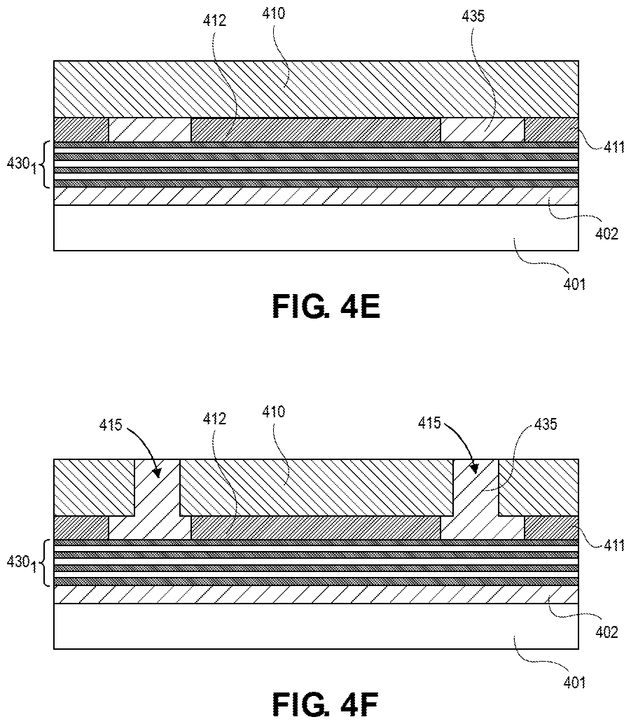

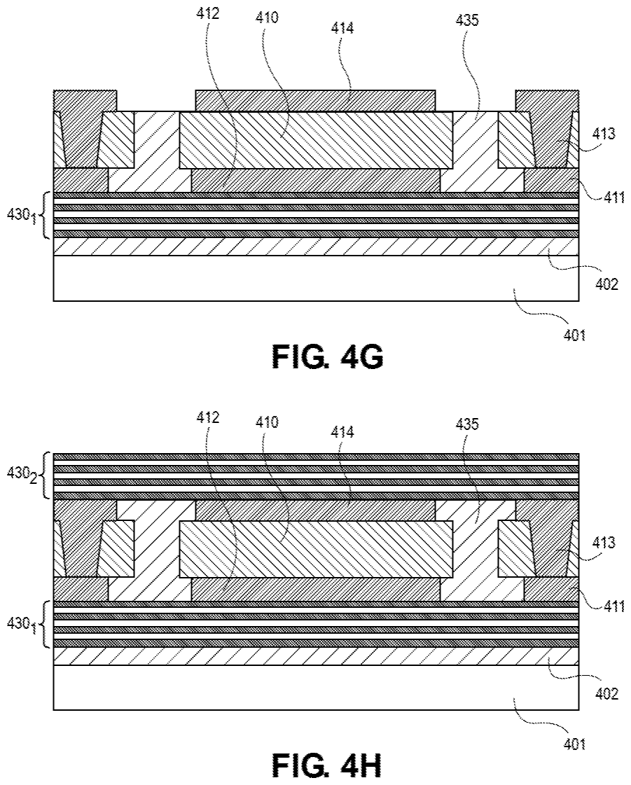

Referring now to FIGS. 4A-4H, a series of cross-sectional illustrations depicting a process for forming a resonator with acoustic reflectors is shown, in accordance with an embodiment. The resonator fabricated in FIGS. 4A-4H may be substantially similar to the resonators 300 illustrated in FIG. 3A or 3B.

Referring now to FIG. 4A, a cross-sectional illustration of a substrate 420 and resonator film 410 is shown, in accordance with an embodiment. In an embodiment, the substrate 420 may be a single crystalline substrate, such as single crystalline Si. In a particular embodiment, the substrate 420 may be a (111) silicon substrate. In an embodiment, the resonator film 410 may be grown over the substrate 420. For example, the resonator film 410 may be grown with an MOCVD or MBE process. Since a single crystalline substrate is used as the base, a highly crystalline resonator film 410 may be provided, even at small thicknesses T. For example, the thickness T may be between approximately 1 nm and approximately 0.5 μm.

Referring now to FIG. 4B, a cross-sectional illustration after a first electrode 412 is disposed over the resonator film 410 is shown, in accordance with an embodiment. The first electrode 412 may be any suitable conductive material, such as copper. In an embodiment, pads 411 may also be formed during the formation of the first electrode 412. The pads 411 may be electrically coupled to the first electrode 412 by one or more traces out of the plane of FIG. 4B.

Referring now to FIG. 4C, a cross-sectional illustration of the structure after an insulating layer 435 is disposed over the exposed portions of the resonator film 410 and a first acoustic reflector 430₁ is formed is shown, in accordance with an embodiment. In an embodiment, the insulating layer 435 is recessed to be planar with the top surface of the first electrode 412. As such, the first acoustic reflector 430₁ can be formed in direct contact with the first electrode 412. The first acoustic reflector 430₁ may comprise alternating first layers 431 and second layers 432. The first layers 431 may comprise a heavy acoustic impedance material (e.g., W), and the second layers 432 may comprise a light acoustic impedance material (e.g., SiO₂).

Referring now to FIG. 4D, a cross-sectional illustration of the structure, after the first acoustic reflector 430₁ is bonded to a substrate 401 is shown, in accordance with an embodiment. In an embodiment, the first acoustic reflector 430₁ is adhered to the substrate 401 by an insulating layer 402, such as an oxide. The bonding may be referred to as a wafer-to-wafer bonding process.

Referring now to FIG. 4E, a cross-sectional illustration after the substrate 420 is removed is shown, in accordance with an embodiment. The complete removal of the substrate 420 may result in a resonator similar to the resonator 300 shown in FIG. 3A. However, the entirety of the substrate 420 may not be removed in some embodiments. The residual portion of the substrate 420 may be used as a tuning layer, similar to the tuning layer 321 shown in the embodiment illustrated in FIG. 3B. Moving forward in the process flow, an embodiment where the complete removal of the substrate 420 is shown, but it is to be appreciated that similar processing operations may be implemented with a residual portion of the substrate 420 remaining.

The substrate 420 may be removed (partially or completely) with any suitable process. For example, a grinding or polishing process may be used to remove the substrate 420. In an alternative embodiment, an ion cutting process may be used to remove some or all of the substrate 420. An ion cutting process may include implanting hydrogen into the substrate 420 to a depth where the cut is desired to be made. A subsequent annealing process may be used to split the substrate 420 at a desired position.

Referring now to FIG. 4F, a cross-sectional illustration of the structure after isolation trenches 415 are formed through the resonator film 410 and filled with a dielectric 435 is shown, in accordance with an embodiment. The isolation trench 415 (because the resonator film 410 does not need to be suspended since it is supported by the underlying structures 412/430/402/401) may mechanically decouple a substantial portion of an interior region of the resonator film 410 that is proximate to the first electrode 412 from an exterior region of the resonator film 410. In an embodiment, the isolation trench 415 may have vertical sidewalls, as shown. In other embodiments, the isolation trench 415 may have a tapered profile characteristic of a laser drilling process. After formation of the isolation trench 415, insulative material 435 may be deposited into the isolation trench 415.

Referring now to FIG. 4G, a cross-sectional illustration of the structure after a second electrode 414 and conductive vias 413 are formed is shown, in accordance with an embodiment. In an embodiment, the second electrode 414 is positioned substantially above the first electrode 412 within a perimeter defined by the isolation trench 415. The vias 413 may land on the pads 411 to provide electrical coupling of the first electrode 412 to the opposite surface of the resonator film 410.

Referring now to FIG. 4H, a cross-sectional illustration of the structure after a second acoustic reflector 430₂ is disposed over a surface of the second electrode 414 is shown, in accordance with an embodiment. In an embodiment, the second acoustic reflector 430₂ may be substantially similar to the first acoustic reflector 430₁. The second acoustic reflector 430₂ is in direct contact with the second electrode 414.

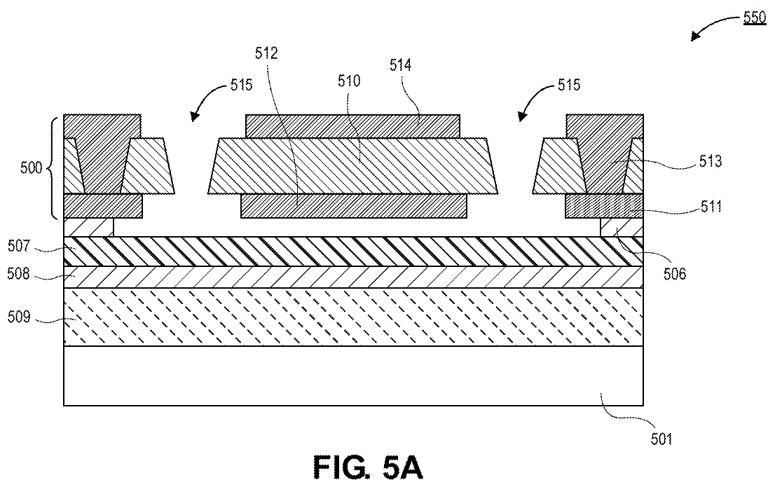

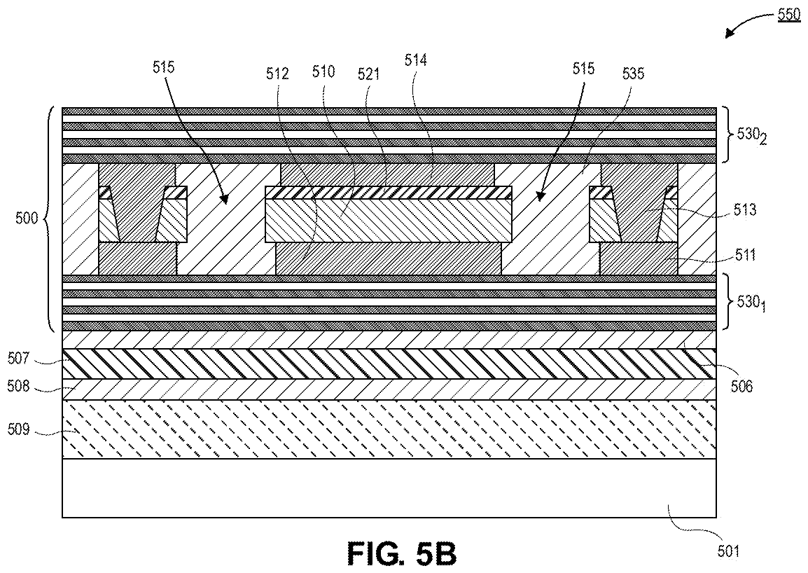

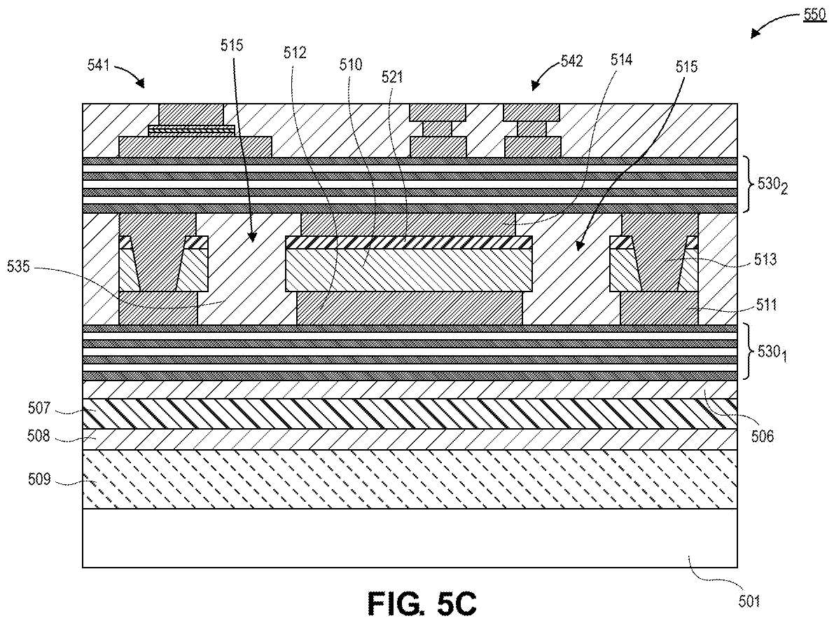

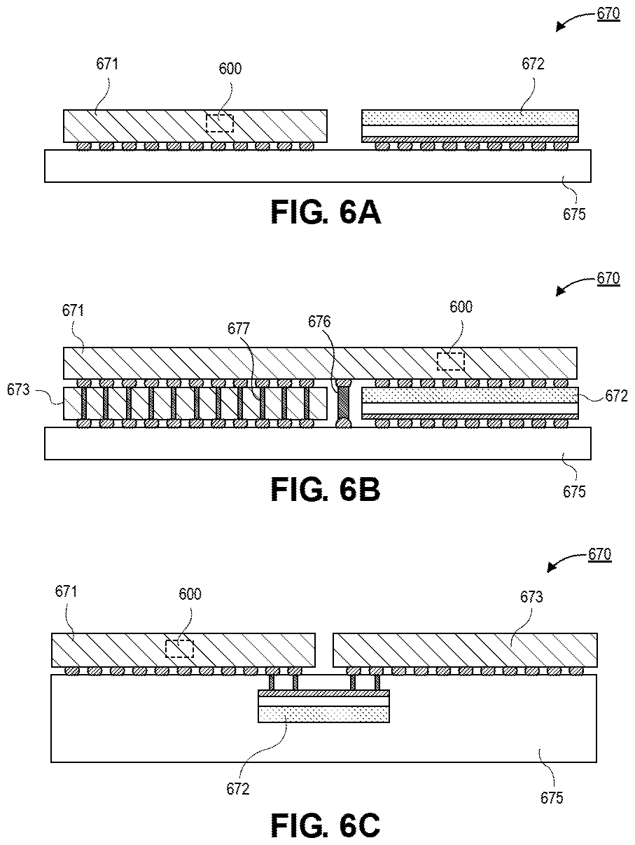

In FIGS. 1A-4H, resonators are shown substantially in isolation. However, it is to be appreciated that the resonators may be integrated in many different architectures. FIGS. 5A-5C provide examples of wafer level integration, and FIGS. 6A-6C provide examples of package level integration.

Referring now to FIG. 5A, a cross-sectional illustration of a device 550 is shown, in accordance with an embodiment. In an embodiment, the device 550 comprises a resonator 500 that is disposed over underlying layers of semiconductor devices. The resonator 500 may be substantially similar to the resonators 100 in FIGS. 1A-1C. For example, the resonator 500 comprises a resonator film 510 with release vias 515. A first electrode 512 and a second electrode 514 are on opposite surfaces of the resonator film 510 within a perimeter defined by the release vias 515. A pad 511 that is electrically coupled to the first electrode 512 may be connected to a via 513. A portion of insulating layer 506 may raise the first electrode 512 up from the underlying substrate layers.

In an embodiment, the underlying substrate layers may comprise a base layer 501, such as a silicon substrate. In an embodiment, a first transistor layer 509 may be disposed over the base layer 501. In an embodiment, the first transistor layer 509 may comprise transistor devices fabricated with a first semiconductor material. In an embodiment, an insulating layer 508 is deposited over the first transistor layer 509. A second transistor layer 507 may be formed over the insulating layer 508. The second transistor layer 507 may comprise transistor devices fabricated with a second semiconductor material. In a particular embodiment, the first semiconductor material comprises GaN, and the second semiconductor material comprises silicon. In an embodiment, the second transistor layer 507 comprises 3D silicon CMOS technology.

Referring now to FIG. 5B, a cross-sectional illustration of a device 550 with an embedded resonator 500 is shown, in accordance with an embodiment. In an embodiment, the underlying layers 501-509 may be substantially similar to those described above with respect to FIG. 5A. FIG. 5B differs in that the resonator 500 includes a resonator film 510 embedded by an insulator 535 and acoustic reflectors 5301 and 5302. Additionally, a tuning layer 521 is shown between the second electrode 514 and the resonator film 510. The tuning layer 521 may comprise silicon or another crystalline semiconductor.

Referring now to FIG. 5C, a cross-sectional illustration of a device 550 is shown, in accordance with an additional embodiment. The device 550 in FIG. 5C is substantially similar to the device 550 in FIG. 5B, with the exception that passive devices 541/542 are disposed above the embedded resonator film 510. Since the first and second acoustic reflectors 5301 and 5302 allow for vibration, the passive devices 541/542 may be provided above the resonator film 510. The passive devices 541/542 may be high quality (high Q) passives, such as metal-insulator-metal (MIM) capacitors 541 and inductors 542.

Referring now to FIG. 6A, a cross-sectional illustration of a device 670 with a package level integration of the resonator 600 is shown, in accordance with an embodiment. In an embodiment, the device 670 comprises a package substrate 675. The package substrate 675 may be attached to a board (not shown), such as a printed circuit board (PCB), a mother board, or the like. A first die 671 and a second die 672 are coupled to the package substrate 675 by interconnects. In an embodiment, the first die 671 may be an RF filter die that comprises a plurality of resonators 600 (indicated schematically with a dashed box). The resonators 600 may be substantially similar to any of the resonators described above. In an embodiment, the second die 672 may be a GaN and Si CMOS die.

Referring now to FIG. 6B, a cross-sectional illustration of a device 670 with copper pillar 676 and through-silicon via (TSV) 677 architecture is shown, in accordance with an embodiment. As shown, a second die 672 and a third die 673 are coupled to the package substrate 675. The package substrate 675 may be attached to a board (not shown), such as a PCB, a mother board, or the like. A first die 671 is coupled to the backside surfaces of the second die 672 and the third die 673. TSVs 677 may provide electrical coupling from the first die 671 to the package substrate 675. Copper pillars 676 may provide electrical coupling from die 671 directly to the package substrate 675, providing substantially lower resistance and parasitic coupling compared to the TSVs 677. In an embodiment, the first die 671 is an RF filter die that comprises a plurality of resonators 600 (indicated schematically with a dashed box). The resonators 600 may be substantially similar to any of the resonators described above. In an embodiment, the second die 672 may be a die containing GaN and Si CMOS transistor technologies, and the third die 673 may be any type of die.

Referring now to FIG. 6C, a cross-sectional illustration of a device 670 is shown, in accordance with an additional embodiment. In an embodiment, the device 670 may have an embedded multi-die interconnect bridge (EMIB) structure. That is, a second die 672 may be embedded in the package substrate 675. The package substrate 675 may be attached to a board (not shown), such as a PCB, a mother board, or the like. The second die 672 may provide electrical coupling between a first die 671 and a third die 673. In an embodiment, the first die 671 is an RF filter die that comprises a plurality of resonators 600 (indicated schematically with a dashed box). The resonators 600 may be substantially similar to any of the resonators described above. In an embodiment, the second die 672 may be a GaN and Si CMOS die, and the third die 673 may be any type of die.

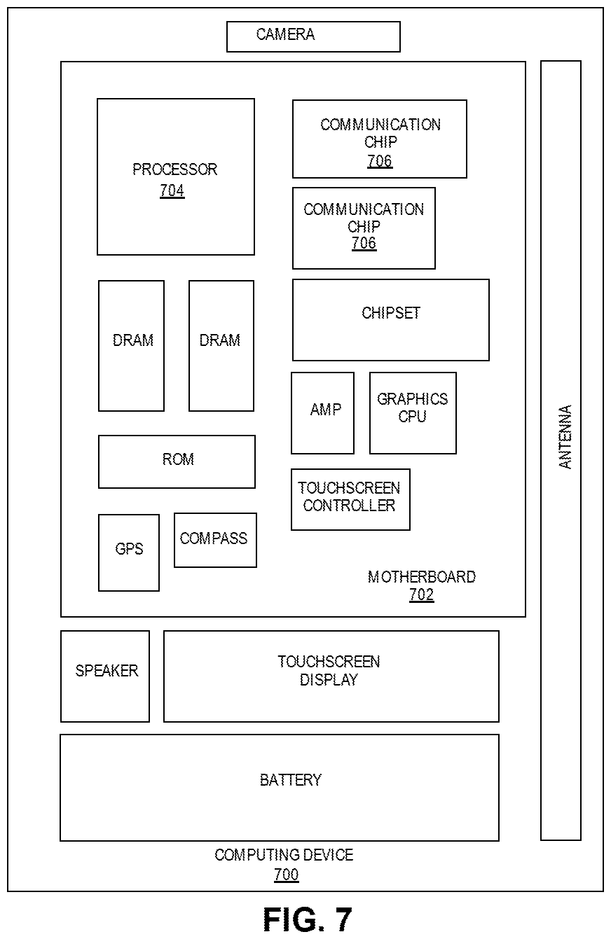

FIG. 7 illustrates a computing device 700 in accordance with one implementation of an embodiment of the disclosure. The computing device 700 houses a board 702. The board 702 may include a number of components, including but not limited to a processor 704 and at least one communication chip 706. The processor 704 is physically and electrically coupled to the board 702. In some implementations the at least one communication chip 706 is also physically and electrically coupled to the board 702. In further implementations, the communication chip 706 is part of the processor 704.

Depending on its applications, computing device 700 may include other components that may or may not be physically and electrically coupled to the board 702. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 706 enables wireless communications for the transfer of data to and from the computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 706 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 700 may include a plurality of communication chips 706. For instance, a first communication chip 706 may be dedicated to shorter range wireless communications such as Wi-Fi and Bluetooth and a second communication chip 706 may be dedicated to longer range wireless communications such as GPS, EDGE, GPRS, CDMA, WiMAX, LTE, Ev-DO, and others.

The processor 704 of the computing device 700 includes an integrated circuit die packaged within the processor 704. In an embodiment, the integrated circuit die of the processor may comprise a resonator with a single crystalline resonator film that has a thickness less than 50 μm, such as those described herein. The term “processor” may refer to any device or portion of a device that processes electronic data from registers and/or memory to transform that electronic data into other electronic data that may be stored in registers and/or memory.

The communication chip 706 also includes an integrated circuit die packaged within the communication chip 706. In an embodiment, the integrated circuit die of the communication chip may comprise a resonator with a single crystalline resonator film that has a thickness less than 50 μm, such as those described herein.

In further implementations, another component housed within the computing device 700 may comprise a resonator with a single crystalline resonator film that has a thickness less than 50 μm, such as those described herein.

In various implementations, the computing device 700 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 700 may be any other electronic device that processes data.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

Example 1: a resonator, comprising: a substrate, wherein a cavity is disposed into a surface of the substrate; a piezoelectric film suspended over the cavity, wherein the piezoelectric film has a first surface and a second surface opposite from the first surface, and wherein the piezoelectric film is single crystalline and has a thickness that is 0.5 μm or less; a first electrode over the first surface of the piezoelectric film; and a second electrode over the second surface of the piezoelectric film.

Example 2: the resonator of Example 1, wherein the piezoelectric film comprises AlN, ScAlN, PZT, LiNbO₃, or LiTaO₃.

Example 3: the resonator of Example 1 or Example 2, further comprising: a plurality of release vias through the piezoelectric film.

Example 4: the resonator of Example 3, wherein the plurality of release vias define a resonating portion of the piezoelectric film suspended over the cavity and surrounded by the plurality of release vias and a static portion of the piezoelectric film outside of the cavity area.

Example 5: the resonator of Example 4, wherein individual ones of the plurality of release vias are substantially circular.

Example 6: the resonator of Example 4, wherein individual ones of the plurality of release vias are rectangular.

Example 7: the resonator of Examples 4-6, further comprising: a plurality of conductive vias through the static portion of the piezoelectric film, wherein the plurality of conductive vias are electrically coupled to the first electrode.

Example 8: the resonator of Example 7, wherein a pad at an end of the conductive vias is separated from the substrate by an insulating layer.

Example 9: the resonator of Examples 1-8, wherein the substrate is a silicon substrate.

Example 10: the resonator of Examples 1-9, further comprising: a semiconductor layer between the piezoelectric film and the second electrode.

Example 11: a resonator, comprising: a substrate; a first acoustic reflector over the substrate; a first electrode over the first acoustic reflector; a piezoelectric film over the first electrode, wherein the piezoelectric film is single crystalline and has a thickness that is 0.5 μm or less; a second electrode over the piezoelectric film; and a second acoustic reflector over the second electrode.

Example 12: the resonator of Example 11, wherein the piezoelectric film comprises AlN, ScAlN, PZT, LiNbO₃, or LiTaO₃.

Example 13: the resonator of Example 11 or Example 12, further comprising: a dielectric layer surrounding the first electrode, the piezoelectric film, and the second electrode.

Example 14: the resonator of Examples 11-13, wherein the first acoustic reflector and the second acoustic reflector comprise: first layers with a first acoustic impedance; and second layers with a second acoustic impedance, wherein the first layers and the second layers are alternated.

Example 15: the resonator of Example 14, wherein the first layers comprise W, and wherein the second layers comprise SiO₂.

Example 16: the resonator of Examples 11-15, further comprising: an isolation trench through and enclosing a portion of the piezoelectric film.

Example 17: the resonator of Example 16, wherein the isolation trench defines a resonating portion of the piezoelectric film within the portion enclosed by the isolation trench and a static portion of the piezoelectric film outside the enclosure.

Example 18: the resonator of Example 16 or Example 17, further comprising: a plurality of conductive vias through the static portion of the piezoelectric film, wherein the plurality of conductive vias are electrically coupled to the first electrode.

Example 19: the resonator of Examples 11-18, further comprising: a silicon layer between the piezoelectric film and the second electrode.

Example 20: a semiconductor device, comprising: a silicon substrate; a first transistor layer over the silicon substrate, wherein the first transistor layer comprises a first semiconductor; a second transistor layer over the first transistor layer, wherein the second transistor layer comprises a second semiconductor that is different than the first semiconductor; and a resonator over the second transistor layer, wherein the resonator comprises a piezoelectric film, and wherein the piezoelectric film is single crystalline and has a thickness that is 0.5 μm or less.

Example 21: the semiconductor device of Example 20, wherein the first semiconductor is GaN, and wherein the second semiconductor is Si.

Example 22: the semiconductor device of Example 20 or Example 21, further comprising: a first acoustic reflector between the resonator and the second transistor layer; and a second acoustic reflector over the resonator.

Example 23: the semiconductor device of Example 22, further comprising: one or more passives over the second acoustic reflector.

Example 24: an electronic system, comprising: a board; an electronic package coupled to the board; an RF filter die coupled to the electronic package, wherein the RF filter die comprises a resonator with a piezoelectric film, wherein the piezoelectric film is single crystalline and has a thickness that is 0.5 μm or less; and a heterogeneous die comprising a first semiconductor and a second semiconductor.

Example 25: the electronic system of Example 24, wherein the piezoelectric film comprises AlN, ScAlN, PZT, LiNbO₃, or LiTaO₃.

What is claimed is:

1. A resonator, comprising:
a substrate, wherein a cavity is disposed into a surface of the substrate;
a piezoelectric film suspended over the cavity, wherein the piezoelectric film has a first surface and a second surface opposite from the first surface, and wherein the piezoelectric film is single crystalline and has a thickness that is 0.5 μm or less;
a first electrode over the first surface of the piezoelectric film; and
a second electrode over the second surface of the piezoelectric film.

2. The resonator of claim 1, wherein the piezoelectric film comprises AlN, ScAlN, PZT, LiNbO₃, or LiTaO₃.

3. The resonator of claim 1, further comprising:
a plurality of release vias through the piezoelectric film.

4. The resonator of claim 3, wherein the plurality of release vias define a resonating portion of the piezoelectric film suspended over the cavity and surrounded by the plurality of release vias and a static portion of the piezoelectric film outside of the cavity area.

5. The resonator of claim 4, wherein individual ones of the plurality of release vias are substantially circular.

6. The resonator of claim 4, wherein individual ones of the plurality of release vias are rectangular.

7. The resonator of claim 4, further comprising:
a plurality of conductive vias through the static portion of the piezoelectric film, wherein the plurality of conductive vias are electrically coupled to the first electrode.

8. The resonator of claim 7, wherein a pad at an end of the conductive vias is separated from the substrate by an insulating layer.

9. The resonator of claim 1, wherein the substrate is a silicon substrate.

10. The resonator of claim 1, further comprising:
a semiconductor layer between the piezoelectric film and the second electrode.

11. A resonator, comprising:
a substrate;
a first acoustic reflector over the substrate;
a first electrode over the first acoustic reflector;
a piezoelectric film over the first electrode, wherein the piezoelectric film is single crystalline and has a thickness that is 0.5 μm or less;
a second electrode over the piezoelectric film; and
a second acoustic reflector over the second electrode.

12. The resonator of claim 11, wherein the piezoelectric film comprises AlN, ScAlN, PZT, LiNbO₃, or LiTaO₃.

13. The resonator of claim 11, further comprising:
a dielectric layer surrounding the first electrode, the piezoelectric film, and the second electrode.

14. The resonator of claim 11, wherein the first acoustic reflector and the second acoustic reflector comprise:
first layers with a first acoustic impedance; and
second layers with a second acoustic impedance, wherein the first layers and the second layers are alternated.

15. The resonator of claim 14, wherein the first layers comprise W, and wherein the second layers comprise SiO₂.

16. The resonator of claim 11, further comprising:
an isolation trench through and enclosing a portion of the piezoelectric film.

17. The resonator of claim 16, wherein the isolation trench defines a resonating portion of the piezoelectric film within the portion enclosed by the isolation trench and a static portion of the piezoelectric film outside the enclosure.

18. The resonator of claim 16, further comprising:
a plurality of conductive vias through the static portion of the piezoelectric film, wherein the plurality of conductive vias are electrically coupled to the first electrode.

19. The resonator of claim 11, further comprising:
a silicon layer between the piezoelectric film and the second electrode.

20. A semiconductor device, comprising:
a silicon substrate;
a first transistor layer over the silicon substrate, wherein the first transistor layer comprises a first semiconductor;
a second transistor layer over the first transistor layer, wherein the second transistor layer comprises a second semiconductor that is different than the first semiconductor; and
a resonator over the second transistor layer, wherein the resonator comprises a piezoelectric film, and wherein the piezoelectric film is single crystalline and has a thickness that is 0.5 μm or less.

21. The semiconductor device of claim 20, wherein the first semiconductor is GaN, and wherein the second semiconductor is Si.

22. The semiconductor device of claim 20, further comprising:
a first acoustic reflector between the resonator and the second transistor layer; and
a second acoustic reflector over the resonator.

23. The semiconductor device of claim 22, further comprising:
one or more passives over the second acoustic reflector.

24. An electronic system, comprising:
a board;
an electronic package coupled to the board;
an RF filter die coupled to the electronic package, wherein the RF filter die comprises a resonator with a piezoelectric film, wherein the piezoelectric film is single crystalline and has a thickness that is 0.5 μm or less; and
a heterogeneous die comprising a first semiconductor and a second semiconductor.

25. The electronic system of claim 24, wherein the piezoelectric film comprises AlN, ScAlN, PZT, LiNbO₃, or LiTaO₃.
